(19) United States
(12) Patent Application Publication
(10) Pub. No.: US 2026/0090183 A1
(43) Pub. Date: Mar. 26, 2026

(54) INFRARED FULL COLOR IMAGE SENSOR

(71) Applicant: Powerchip Semiconductor Manufacturing Corporation, Hsinchu (TW)

(72) Inventors: Chao-Hsin Wu, Hsinchu (TW); Chee Keong Yee, Hsinchu (TW); Ming-June Wu, Hsinchu (TW); Yi-Tzu Tseng, Hsinchu (TW); Natchanon Prechatavanich, Hsinchu (TW); Theeradech Sutheebanjerd, Hsinchu (TW)

(73) Assignee: Powerchip Semiconductor Manufacturing Corporation, Hsinchu (TW)

(21) Appl. No.: 18/931,117

(22) Filed: Oct. 30, 2024

(30) Foreign Application Priority Data
Sep. 20, 2024 (TW) 113135777

(51) Int. Cl. H10K 39/32; H04N 25/131

(52) U.S. Cl. CPC H10K 39/32; H04N 25/131

(57) ABSTRACT

An infrared (IR) full color image sensor includes a CMOS image sensor (CIS), isolation components, red light conversion units, green light conversion units and blue light conversion units. The isolation components are disposed on the CIS to define a plurality of conversion areas. The red light, the green light and the blue light conversion units are respectively located in different conversion areas. Each conversion unit includes an IR filter, an anode layer, a first electron transport layer, a light-absorbing quantum dot layer, a hole transport layer, a light-emitting quantum dot layer, a second electron transport layer and a cathode layer. The cathode layer is in direct contact with the CIS. The light-absorbing quantum dot layer absorbs IR that enters the conversion area through the IR filter and then generates electron-hole pairs. Electron-hole pairs are recombined in the light-emitting quantum dot layer to excite red, green, and blue visible lights.

### CROSS-REFERENCE TO RELATED APPLICATION

This application claims the priority benefit of Taiwan application serial no. 113135777, filed on Sep. 20, 2024. The entirety of the above-mentioned patent application is hereby incorporated by reference herein and made a part of this specification.

### BACKGROUND

### Technical Field

The present disclosure relates to an infrared light (IR) sensing technology, and in particular to an infrared full color image sensor which converts an infrared light into visible light using an upconversion method, which is integrated with a CMOS image sensing system.

### Description of Related Art

Infrared sensors are widely utilized in sensing equipment for environmental monitoring and ecological observation. Furthermore, Near-Infrared (NIR) sensors have been implemented in medical diagnostic devices, such as blood oxygen monitoring equipment.

### SUMMARY

The present disclosure provides an infrared full color image sensor that utilizes the principle of upconversion to convert infrared light into visible light and subsequently transform the visible light into image for output.

An infrared (IR) full color image sensor of the present disclosure includes a CMOS image sensor (CIS), an isolation component, a red light conversion unit, a green light conversion unit and a blue light conversion unit. The isolation component is disposed on the CIS to define a plurality of conversion areas. The red light conversion unit, the green light conversion unit and the blue light conversion unit are respectively disposed in different conversion areas. Each of the red light conversion unit, the green light conversion unit, and the blue light conversion unit includes an anode layer and a cathode layer, an IR filter, a hole transport layer, a first electron transport layer, a second electron transport layer, a light-absorbing quantum dot layer and a light-emitting quantum dot layer. The cathode layer is in direct contact with the CMOS image sensor. The IR filter is disposed on the anode layer. The hole transport layer is disposed between the cathode layer and the anode layer. The first electron transport layer is disposed between the anode layer and the hole transport layer. The second electron transport layer is disposed between the cathode layer and the hole transport layer. The light-absorbing quantum dot layer is disposed between the first electron transport layer and the hole transport layer to absorb infrared light in a predetermined wavelength range that enters the conversion area through the IR filter and then generates an electron-hole pair. The light-emitting quantum dot layer is disposed between the second electron transport layer and the hole transport layer to recombine the electron-hole pair to excite at least one of red, green, and blue visible lights to the CMOS image sensor.

In an embodiment of the present disclosure, the cathode layer includes metal, transparent conductive oxide, or a combination thereof.

In an embodiment of the present disclosure, the anode layer includes a transparent electrode.

In an embodiment of the present disclosure, the predetermined wavelength range is between 800 nm and 2000 nm.

In an embodiment of the present disclosure, the IR filter of the red light conversion unit has a first filterable waveband range, and the IR filter of the green light conversion unit has a second filterable waveband range. The IR filter of the blue light conversion unit has a third filterable waveband range. The first filterable waveband range is greater than the second filterable waveband range, and the second filterable waveband range is greater than the third filterable waveband range.

In an embodiment of the present disclosure, the light-absorbing quantum dot layer of the red light conversion unit is a quantum dot material that absorbs infrared light in the first filterable waveband range and excites the electron-hole pair.

In an embodiment of the present disclosure, the light-absorbing quantum dot layer of the green light conversion unit is a quantum dot material that absorbs infrared light in the second filterable waveband range and excites the electron-hole pair.

In an embodiment of the present disclosure, the light-absorbing quantum dot layer of the blue light conversion unit is a quantum dot material that absorbs infrared light in the third filterable waveband range and excites the electron-hole pair.

In an embodiment of the present disclosure, the light-emitting quantum dot layer of the red light conversion unit is a quantum dot material with a light-emitting wavelength of 590 nm to 800 nm.

In an embodiment of the present disclosure, the light-emitting quantum dot layer of the green light conversion unit is a quantum dot material with a light-emitting wavelength of 480 nm to 590 nm.

In an embodiment of the present disclosure, the light-emitting quantum dot layer of the blue light conversion unit is a quantum dot material with a light-emitting wavelength of 380 nm to 480 nm.

In an embodiment of the present disclosure, the CMOS image sensor is configured to receive the red light, green light and blue light emitted by the light-emitting quantum dot layer and generate an image.

In an embodiment of the present disclosure, the materials of the first electron transport layer and the second electron transport layer respectively include zinc oxide (ZnO) doped with aluminum, magnesium, or gallium; titanium dioxide (TiO₂); tin dioxide (SnO₂); bathocuproine (BCP); or [6,6]-phenyl-C61-butyric acid methyl ester (PCBM). Furthermore, the materials of the first and second electron transport layers may also utilize other materials conducive to electron transport and are not limited to the materials enumerated above.

In an embodiment of the present disclosure, the material of the hole transport layer includes poly[bis(4-phenyl)(4-butylphenyl)amine] (Poly-TPD), poly(N-vinylcarbazole) (PVK), poly(9,9-dioctylfluorene-co-N-(4-(3-methylpropyl))diphenylamine) (TFB), 4,4′-bis(N-carbazolyl)biphenyl (CBP), 4,4′-bis[N-(1-naphthyl)-N-phenylamino]biphenyl (NPB), 4,4′,4″-tris(carbazol-9-yl)triphenylamine (TcTa), N,N′-bis(3-methylphenyl)-N,N′-bis(phenyl)-9,9-spirobifluorene (Spiro-TPD), or tris[N-(pyridin-2-ylmethyl)-2-aminoethyl]amine (TPAA). In addition to the aforementioned materials, other materials facilitating hole transport may also be employed for the hole transport layer, and are not limited to the materials enumerated above.

In order to make the above-mentioned features of the present disclosure more obvious and easy to understand, embodiments are given below and described in detail with reference to the attached drawings.

### BRIEF DESCRIPTION OF THE DRAWINGS

FIG. 1 is a cross-sectional view of an infrared full color image sensor according to an embodiment of the present disclosure.

FIG. 2 is a schematic diagram of the operating mechanism of the infrared full color image sensor of FIG. 1.

FIG. 3 is an energy band diagram of the red light, green light and blue light conversion units in an example of the infrared full color image sensor of FIG. 1.

### DESCRIPTION OF THE EMBODIMENTS

The present disclosure may be understood by referring to the following detailed description in conjunction with the accompanying drawings. Furthermore, the dimensions of each area in the figures are only for illustration and are not intended to limit the scope of the present disclosure.

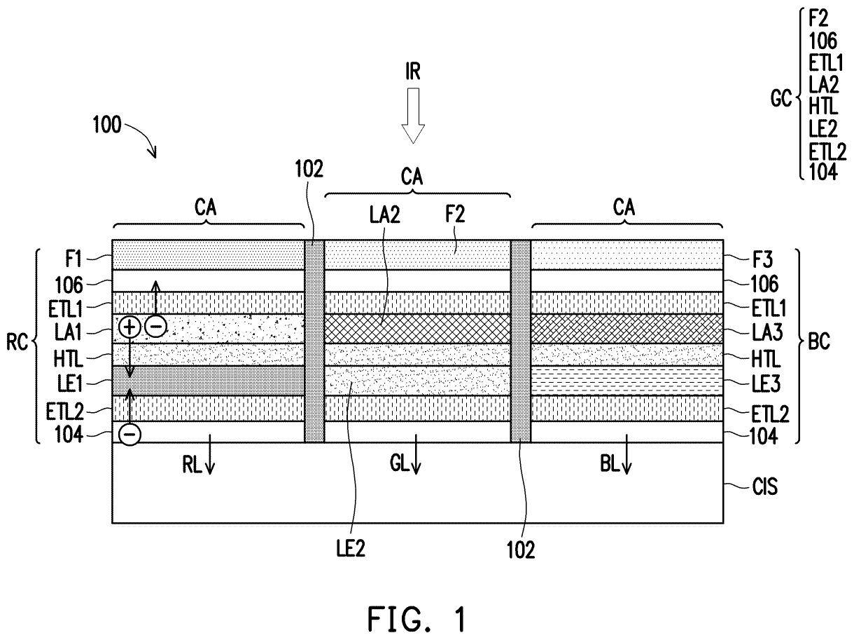

FIG. 1 is a cross-sectional view of an infrared full color image sensor according to an embodiment of the present disclosure.

Please refer to FIG. 1. The infrared full color image sensor 100 of this embodiment includes a CMOS image sensor CIS, an isolation component 102, a red light conversion unit RC, a green light conversion unit GC and a blue light conversion unit BC. The isolation component 102 is disposed on the CMOS image sensor CIS to define a plurality of conversion areas CA. The isolation component 102 may include black resin or light-absorbing materials such as metal grids or may be made of epoxy resin, acrylic resin, siloxane polymer resin, polyimide resin, etc. to separate different conversion areas CA so that they do not interfere with each other. The isolation component 102 may be formed by a wet coating method or a dry process. The red light conversion unit RC, the green light conversion unit GC and the blue light conversion unit BC are respectively disposed in different conversion areas CA. Although only one red light conversion unit RC, one green light conversion unit GC and one blue light conversion unit BC are shown in the figure, it should be understood that the number of the red light conversion unit RC, green light conversion unit GC and blue light conversion unit BC and arrangement method thereof may vary depending on requirement, or a single conversion unit may be regarded as a pixel and disposed on the CMOS image sensor CIS according to the design.

The red light conversion unit RC, green light conversion unit GC, and blue light conversion unit BC each include: a cathode layer 104 and an anode layer 106, an IR filter F1/F2/F3, a hole transport layer HTL, a first electron transport layer ETL1, a second electron transport layer ETL2, a light-absorbing quantum dot layer LA1/LA2/LA3, and a light-emitting quantum dot layer LE1/LE2/LE3. The symbol “/” in the text may represent “and” or “or.” Specifically, the red light conversion unit RC includes a cathode layer 104 and an anode layer 106, an IR filter F1, a hole transport layer HTL, a first electron transport layer ETL1, a second electron transport layer ETL2, a light-absorbing quantum dot layer LA1, and a light-emitting quantum dot layer LE1; the green light conversion unit GC includes a cathode layer 104 and an anode layer 106, an IR filter F2, a hole transport layer HTL, a first electron transport layer ETL1, a second electron transport layer ETL2, a light-absorbing quantum dot layer LA2, and a light-emitting quantum dot layer LE2; the blue light conversion unit BC includes a cathode layer 104 and an anode layer 106, an IR filter F3, a hole transport layer HTL, a first electron transport layer ETL1, a second electron transport layer ETL2, a light-absorbing quantum dot layer LA3, and a light-emitting quantum dot layer LE3.

In some embodiments, the cathode layer 104 may include metal, transparent conductive oxide, or a combination thereof, such as a multilayer structure consisting of OMO (transparent conductive oxide/metal/transparent conductive oxide), but not limited thereto. The metal may include silver (Ag), aluminum (Al), etc., while the transparent conductive oxide may include indium tin oxide (ITO), tungsten oxide (WO₃), zinc oxide (ZnO), aluminum-doped zinc oxide (AZO), gallium-doped zinc oxide (GZO), etc. In some embodiments, the anode layer 106 includes a transparent electrode, such as ITO, WO₃, ZnO, AZO, GZO, other similar materials, or combinations thereof. The cathode layer 104 and the anode layer 106 may each be formed through plating, sputtering, or other similar methods.

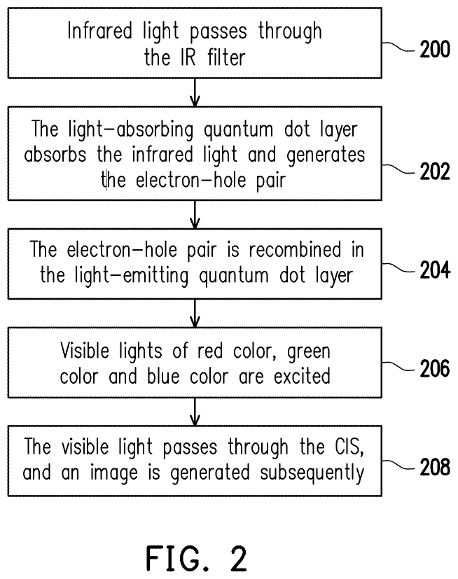

Referring again to FIG. 1, the cathode layer 104 is in direct contact with the CMOS image sensor CIS, without the need for any intervening circuit layers. The red light conversion unit RC, green light conversion unit GC, and blue light conversion unit BC may be directly formed on the CMOS image sensor CIS. The IR filters F1/F2/F3 are disposed on the anode layer 106, and the IR filter F1, the IR filter F2, and the IR filter F3 allow infrared light of different wavelength ranges to pass through. For example, the IR filter F1 of the red light conversion unit RC has a first filterable waveband range Δλ1, the IR filter F2 of the green light conversion unit GC has a second filterable waveband range Δλ2, and the IR filter F3 of the blue light conversion unit BC has a third filterable waveband range Δλ3, satisfying the condition Δλ1>Δλ2>Δλ3. The hole transport layer HTL is disposed between the cathode layer 104 and the anode layer 106. The first electron transport layer ETL1 is disposed between the anode layer 106 and the hole transport layer HTL. The second electron transport layer ETL2 is disposed between the cathode layer 104 and the hole transport layer HTL. The light-absorbing quantum dot layers LA1/LA2/LA3 are disposed between the first electron transport layer ETL1 and the hole transport layer HTL, and configured to absorb infrared light within a predetermined wavelength range that enters the conversion area CA through the IR filters F1/F2/F3 (as shown in step 200 of FIG. 2) and generate the electron-hole pair (as shown in step 202 of FIG. 2). In some embodiments, the predetermined wavelength range is between 800 nm and 2000 nm. The light-absorbing quantum dot layer LA1 of the red light conversion unit RC is made of quantum dot materials that absorb infrared light within the first filterable waveband range Δλ1 and excite the electron-hole pair. The light-absorbing quantum dot layer LA2 of the green light conversion unit GC is made of quantum dot materials that absorb infrared light within the second filterable waveband range Δλ2 and excite the electron-hole pair. The light-absorbing quantum dot layer LA3 of the blue light conversion unit BC is made of quantum dot materials that absorb infrared light within the third filterable waveband range Δλ3 and excite the electron-hole pair. In some embodiments, the materials of the light-absorbing quantum dot layers LA1/LA2/LA3 include lead sulfide (PbS), lead selenide (PbSe), indium arsenide (InAs), bismuth selenide (Bi₂Se₃), or other materials with similar properties. The light-absorbing quantum dot layers LA1/LA2/LA3 may be formed through spin coating, inkjet printing, or other similar methods.

In some embodiments, the materials of the first electron transport layer ETL1 and the second electron transport layer ETL2 respectively include zinc oxide (ZnO) doped with aluminum, magnesium, or gallium; titanium oxide (TiO₂); tin oxide (SnO₂), bathocuproine (BCP); [6,6]-phenyl-C61-butyric acid methyl ester (PCBM); or other similar materials. In alternative embodiments, the materials of the first electron transport layer ETL1 and the second electron transport layer ETL2 may be selected from existing electron transport layer materials, provided they achieve the effect of facilitating electron transport, and are not limited to the aforementioned materials. The first electron transport layer ETL1 and the second electron transport layer ETL2 may each be formed by spin coating, sputtering, or other similar methods. Electrons from the electron-hole pair generated in the light-absorbing quantum dot layer LA1/LA2/LA3 are transported by the first electron transport layer ETL1 to the anode layer 106, while holes from the electron-hole pairs are transported by the hole transport layer HTL to the light-emitting quantum dot layer LE1/LE2/LE3.

In some embodiments, the materials for the hole transport layer HTL include poly[N,N′-bis(4-butylphenyl)-N,N′-bis(phenyl)benzidine] (Poly-TPD), poly(N-vinylcarbazole) (PVK), poly[(9,9-dioctylfluorenyl-2,7-diyl)-co-(4,4′-(N-(4-sec-butylphenyl)diphenylamine)] (TFB), 4,4′-bis(N-carbazolyl)-1,1′-biphenyl (CBP), 4,4′-bis[N-(1-naphthyl)-N-phenylamino]biphenyl (NPB), 4,4′,4″-tris(carbazol-9-yl)triphenylamine (TcTa), N,N′-bis(3-methylphenyl)-N,N′-bis(phenyl)-9,9-spirobifluorene (Spiro-TPD), tris[N-(2-pyridinylmethyl)-2-aminoethyl]amine (TPAA), and other similar materials. In other embodiments, the materials for the hole transport layer HTL may further be selected from existing hole transport layer materials, provided that they can achieve the effect of promoting hole transport, and are not limited to the aforementioned materials. The hole transport layer HTL may be formed through spin coating, sputtering, or other similar methods.

Please refer to FIG. 1. The light-emitting quantum dot layers LE1/LE2/LE3 are disposed between the second electron transport layer ETL2 and the hole transport layer HTL, serving to recombine electron-hole pairs (as shown in step 204 of FIG. 2), wherein holes transported from the hole transport layer HTL to the light-emitting quantum dot layers LE1/LE2/LE3 are recombined with electrons from the cathode layer 104, subsequently exciting different colors of visible light in the light-emitting quantum dot layers LE1/LE2/LE3, which are then emitted to the CMOS image sensor CIS (as shown in step 206 of FIG. 2). For instance, the red color conversion unit RC emits red light RL, the green color conversion unit GC emits green light GL, and the blue color conversion unit BC emits blue light BL. In some embodiments, the light-emitting quantum dot layer LE1 of the red color conversion unit RC is made of quantum dot materials with a light-emitting wavelength in the range of 590 nm to 800 nm. In some embodiments, the light-emitting quantum dot layer LE2 of the green color conversion unit GC is made of quantum dot materials with a light-emitting wavelength in the range of 480 nm to 590 nm. In some embodiments, the light-emitting quantum dot layer LE3 of the blue color conversion unit BC is made of quantum dot materials with a light-emitting wavelength in the range of 380 nm to 480 nm. The CMOS image sensor CIS receives the red light RL, green light GL, and blue light BL emitted from the light-emitting quantum dot layers LE1/LE2/LE3 and subsequently generates an image (as shown in step 208 of FIG. 2). In some embodiments, the materials of the light-emitting quantum dot layers LE1/LE2/LE3 include cadmium selenide/zinc sulfide (CdSe/ZnS) core-shell quantum dots, cadmium telluride (CdTe), cadmium sulfide (CdS), or materials exhibiting similar properties. The light-emitting quantum dot layers LE1/LE2/LE3 may be formed through spin coating, inkjet printing, or other similar methods.

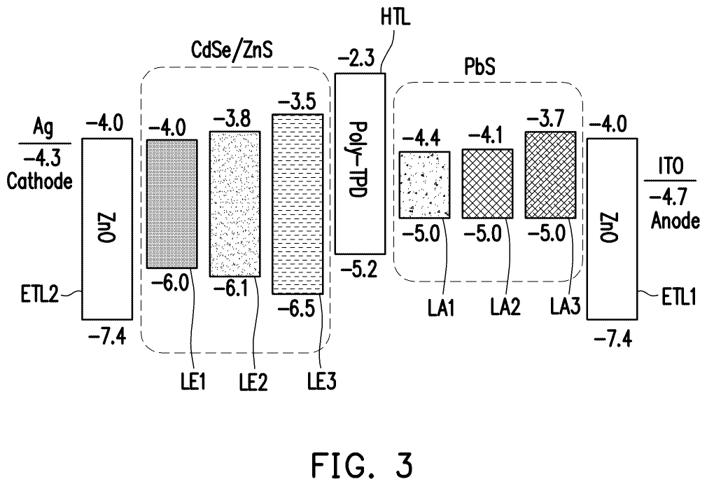

FIG. 3 is an energy band diagram of the red light, green light and blue light conversion units in an example of the infrared full color image sensor of FIG. 1. The diagram demonstrates an instance wherein, through the configuration of energy bands within the materials, it is feasible to implement a method of converting infrared light into visible light utilizing an upconversion process.

In FIG. 3, the cathode is silver (Ag) and the anode is indium tin oxide (ITO). The hole transport layer HTL is Poly-TPD, while both the first electron transport layer ETL1 and the second electron transport layer ETL2 are composed of zinc oxide (ZnO). The light-absorbing quantum dot layer LA1/LA2/LA3 are all comprised of lead sulfide (PbS). The light-emitting quantum dot layers LE1/LE2/LE3 consist of cadmium selenide/zinc sulfide (CdSe/ZnS) core-shell quantum dots. Although the light-absorbing quantum dot layers LA1/LA2/LA3 are composed of the same material, the bandgaps of the light-absorbing quantum dot layer LA1, the light-absorbing quantum dot layer LA2, and the light-absorbing quantum dot layer LA3 may be adjusted by controlling the size of the quantum dots in each respective layer. Similarly, while the light-emitting quantum dot layers LE1/LE2/LE3 are composed of the same material, the bandgaps of the light-emitting quantum dot layer LE1, the light-emitting quantum dot layer LE2, and the light-emitting quantum dot layer LE3 may be adjusted by modifying the size of the quantum dots in each corresponding layer.

When infrared light passes through the filter and enters from the anode side, based on the material properties, infrared light within the predetermined wavelength range is absorbed by the light-absorbing quantum dot layer LA1, the light-absorbing quantum dot layer LA2, and the light-absorbing quantum dot layer LA3, generating electron-hole pairs. The positive terminal of the operating voltage is connected to the anode, while the negative terminal of the operating voltage is connected to the cathode. Electrons, being negatively charged, migrate towards the anode through the first electron transport layer ETL1. Holes, being positively charged, traverse the hole transport layer HTL to enter the light-emitting quantum dot layer LE1/LE2/LE3. Within the light-emitting quantum dot layer LE1, the light-emitting quantum dot layer LE2, and the light-emitting quantum dot layer LE3, the holes recombine with electrons originating from the cathode, thus exciting visible light of different colors.

In view of the above, the present disclosure utilizes an upconversion method to convert infrared light into visible light, and incorporates three conversion units for Red (R), Green (G), and Blue (B) in combination with the CIS. Consequently, upon absorption of R/G/B visible light by the CIS, a full color image is generated.

Although the present disclosure has been disclosed above through embodiments, it is not intended to limit the present disclosure. Anyone with ordinary knowledge in the technical field can make some modifications and refinement without departing from the spirit and scope of the present disclosure, so the protection scope of the present disclosure shall be determined by the appended claims.

What is claimed is:

1. An infrared (IR) full color image sensor, comprising:
a CMOS image sensor;
an isolation component, disposed on the CMOS image sensor to define a plurality of conversion areas; and
a red light conversion unit, a green light conversion unit and a blue light conversion unit, respectively disposed in the plurality of different conversion areas, wherein
each of the red light conversion unit, the green light conversion unit, and the blue light conversion unit comprises:
an anode layer and a cathode layer, wherein the cathode layer is in direct contact with the CMOS image sensor;
an IR filter, disposed on the anode layer;
a hole transport layer, disposed between the cathode layer and the anode layer;
a first electron transport layer, disposed between the anode layer and the hole transport layer;
a second electron transport layer, disposed between the cathode layer and the hole transport layer;
a light-absorbing quantum dot layer, disposed between the first electron transport layer and the hole transport layer to absorb an infrared light in a predetermined wavelength range that enters the conversion area through the IR filter and then generates an electron-hole pair; and
a light-emitting quantum dot layer, disposed between the second electron transport layer and the hole transport layer to recombine the electron-hole pair to excite at least one of red, green, and blue visible lights to the CMOS image sensor.

2. The infrared full color image sensor according to claim 1, wherein the cathode layer comprises a transparent electrode.

3. The infrared full color image sensor according to claim 1, wherein the anode layer comprises a transparent electrode.

4. The infrared full color image sensor according claim 1, wherein the predetermined wavelength range is between 800 nm and 2000 nm.

5. The infrared full color image sensor according to claim 1, wherein the IR filter of the red light conversion unit has a first filterable waveband range, the IR filter of the green light conversion unit has a second filterable waveband range, the IR filter of the blue light conversion unit has a third filterable waveband range, and the first filterable waveband range is greater than the second filterable waveband range, the second filterable waveband range is greater than the third filterable waveband range.

6. The infrared full color image sensor according to claim 5, wherein the light-absorbing quantum dot layer of the red light conversion unit is a quantum dot material that absorbs an infrared light in the first filterable waveband range and excites the electron-hole pair.

7. The infrared full color image sensor according to claim 5, wherein the light-absorbing quantum dot layer of the green light conversion unit is a quantum dot material that absorbs an infrared light in the second filterable waveband range and excites the electron-hole pair

8. The infrared full color image sensor according to claim 5, wherein the light-absorbing quantum dot layer of the blue light conversion unit is a quantum dot material that absorbs an infrared light in the third filterable waveband range and excites the electron-hole pair.

9. The infrared full color image sensor according to claim 1, wherein the light-emitting quantum dot layer of the red light conversion unit is a quantum dot material with a light-emitting wavelength of 590 nm to 800 nm.

10. The infrared full color image sensor according to claim 1, wherein the light-emitting quantum dot layer of the green light conversion unit is a quantum dot material with a light-emitting wavelength of 480 nm to 590 nm.

11. The infrared full color image sensor according to claim 1, wherein the light-emitting quantum dot layer of the blue light conversion unit is a quantum dot material with a light-emitting wavelength of 380 nm to 480 nm.

12. The infrared full color image sensor according to claim 1, wherein the CMOS image sensor is configured to receive a red light, a green light and a blue light emitted by the light-emitting quantum dot layer and generate an image.

13. The infrared full color image sensor according to claim 1, wherein materials of the first electron transport layer and the second electron transport layer respectively comprise zinc oxide (ZnO) doped with aluminum, magnesium, or gallium; titanium dioxide (TiO₂); tin dioxide (SnO₂); bathocuproine (BCP); or [6,6]-phenyl-C61-butyric acid methyl ester (PCBM).

14. The infrared full color image sensor according to claim 1, wherein a material of the hole transport layer comprises poly[bis(4-phenyl)(4-butylphenyl)amine] (Poly-TPD), poly(N-vinylcarbazole) (PVK), poly(9,9-dioctylfluorene-co-N-(4-(3-methylpropyl))diphenylamine) (TFB), 4,4′-bis(N-carbazolyl)biphenyl (CBP), 4,4′-bis[N-(1-naphthyl)-N-phenylamino]biphenyl (NPB), 4,4′,4″-tris(carbazol-9-yl)triphenylamine (TcTa), N,N′-bis(3-methylphenyl)-N,N′-bis(phenyl)-9,9-spirobifluorene (Spiro-TPD), or tris[N-(pyridin-2-ylmethyl)-2-aminoethyl]amine (TPAA).
